(19) United States
(12) Patent Application Publication
(10) Pub. No.: US 2026/0011534 A1
(43) Pub. Date: Jan. 8, 2026

(54) COATING SYSTEM, ELECTRIC GENERATOR, POWER SUPPLY AND USAGE THEREOF

(71) Applicant: VON ARDENNE Asset GmbH & Co. KG, Dresden (DE)

(72) Inventors: Martin KOPTE, Freital (DE); Ruben SEIFERT, Dresden (DE); Marc Tobias WENZEL, Dresden (DE)

(21) Appl. No.: 19/257,029

(22) Filed: Jul. 1, 2025

(30) Foreign Application Priority Data
Jul. 4, 2024 (DE) 10 2024 118 984.3

(51) Int. Cl. H01J 37/32; C23C 14/32

(52) U.S. Cl. CPC H01J 37/32669; C23C 14/325; H01J 37/32064; H01J 37/32697; H01J 2237/3323

(57) ABSTRACT

A coating system for coating a substrate by an arc discharge comprises a target holder for holding a target; a substrate holder arranged along an emission axis behind the target holder for holding a substrate to be coated by the target; an anode for generating an arc discharge between the target holder and the anode, wherein the anode is arranged between the target holder and the substrate holder; an manipulation system arranged along the emission axis behind the anode, which is arranged to generate an electric and/or magnetic field for influencing a plasma propagating from the target holder along the emission axis by the arc discharge. A method for generating a plasma by an arc discharge and for manipulating the plasma by a magnetic field generated by one or more than one electromagnetic coil disposed along the emission axis behind the anode.

### CROSS-REFERENCE TO RELATED APPLICATIONS

This application claims priority pursuant to 35 U.S.C. 119 (a) to German Patent Application No. 10 2024 118 984.3, filed Jul. 4, 2024, which application is incorporated herein by reference in its entirety.

### FIELD OF THE INVENTION

Various embodiments relate to a coating system, an electrical generator, a power supply and usage thereof.

### BACKGROUND

In general, a substrate (e.g., a workpiece) may be coated so that the chemical and/or physical properties of the substrate may be changed. The substrate may be coated in a vacuum in which one or more layers are deposited as a coating on the substrate by physical vapor deposition, of which arc evaporation is an established representative. In arc evaporation, the coating material is converted into the gaseous phase by an arc discharge, which is at least partially ionized due to the high energies involved, i.e., it is present as a plasma.

However, there are still hurdles that make it difficult to achieve high standards for the result of arc evaporation. These requirements include the uniformity of the coating, which is a function of the spread of the gaseous coating material in space (also known as the spread characteristic).

### SUMMARY OF THE INVENTION

According to various embodiments, it has been illustratively recognized that there is additional scope for influencing the arc evaporation. More specifically, it has been recognized that the multidimensional state space of the plasma has been incompletely addressed. Various properties of the plasma that span the multidimensional state space of the plasma are, for example, subject to disturbances and/or variations that may only be compensated for inadequately (e.g., inaccurately) or not at all. Examples of such properties include the composition of the plasma (e.g., degree of ionization and/or composition of electrically charged components of the plasma), rate and/or spatial propagation characteristics of the plasma.

According to various embodiments, the resulting knowledge is addressed by an additional control system, which extends access to the state space of the plasma, in particular for influencing the plasma (e.g., its operating point). For this purpose, a suitable circuit for providing one or more than one generator is provided, which makes it easier to utilize the extended access to the state space of the plasma.

Various examples are described below, which relate to those described herein and illustrated in the figures.

Example 1 is configured in accordance with one of the appended claims and/or is a coating system for coating a substrate by an arc discharge (shortly also referred to as arc discharge), comprising: a target (or at least one target holder); an arc discharge system arranged along an emission axis (e.g., in emission direction) comprising: a substrate holder arranged behind the target (or at least the target holder) for holding a substrate to be coated by the target; an anode for generating the arc discharge mediated (e.g., conveyed) between the target (or at least the target holder) and the anode, wherein the anode is arranged between the target (or at least the target holder) and the substrate holder; and a manipulation system arranged along the emission axis (e.g., emission direction) behind the anode, which is configured to generate a (e.g., pulsed) electric field and/or magnetic field for influencing a plasma (e.g., its spatial distribution) propagating from the target along the emission axis (e.g., emission direction) by the arc discharge.

Example 2 (e.g., a coating system) is configured according to example 1, wherein the manipulation system comprises a capacitive manipulation member (e.g., an electrode) for generating the electric field and/or an inductive manipulation member (e.g., an electromagnet) for generating the magnetic field, which are arranged along the emission axis (e.g., in emission direction) behind the anode.

Example 3 (e.g., a coating system) is configured according to example 1 or 2, wherein the manipulation system (e.g., its inductive manipulation member) has one or more than one electromagnetic coil, preferably two coils, which are disposed one behind the other along the emission axis (e.g., in the direction of emission).

Example 4 (e.g., a coating system) is configured according to any one of examples 1 to 3, wherein the manipulation system (e.g., its inductive manipulation member and/or each coil thereof) comprises one or more than one winding which revolves around the emission axis.

Example 5 (e.g., a coating system) is configured according to one of examples 1 to 4, wherein the manipulation system (e.g., its inductive manipulation member and/or each coil thereof) has a coil axis which is parallel to the emission axis (e.g., emission direction), e.g., coincides with (touching) it.

Example 6 (e.g., a coating system) is configured according to any one of examples 1 to 5, wherein the manipulation system (e.g., its capacitive manipulation member and/or each electrode thereof) is penetrated along the emission axis (e.g., emission direction) by a passage opening (also referred to as passage), the manipulation system comprising e.g., several (e.g., beam-shaped) components (e.g., carriers) which delimit the passage opening.

Example 7 (e.g., a coating system) is configured according to any one of examples 1 to 6, wherein the manipulation system (e.g., its capacitive manipulation member and/or each electrode thereof) is frame-shaped.

Example 8 (e.g., a coating system) is configured according to one of examples 1 to 7, wherein the manipulation system (e.g., its capacitive manipulation member and/or each electrode thereof) and/or the passage has a larger extension (or cross-sectional area transverse to the emission axis) than the anode (e.g., along one or more than one direction (e.g., having a gravitational direction) transverse to the emission axis (e.g., emission direction), of which two directions are, for example, transverse to each other.

Example 9 (e.g., a coating system) is configured according to any one of examples 1 to 8, wherein the manipulation system (e.g., its capacitive manipulation member and/or each electrode thereof) comprises one or more than one pair of (e.g., beam-shaped) components (e.g., beams) between which the emission axis (e.g., emission direction) passes, which have a distance along one or more than one direction transverse to the emission axis (e.g., emission direction) from each other which is greater than an extension of the target (or each electrode thereof), emission direction), which have a distance from each other along one or more than one direction transverse to the emission axis (e.g., emission direction) which is greater than an extension of the target (or at least the target holder) and/or the substrate holder (or at least its receiving area) along the direction.

Example 10 (e.g., a coating system) is configured according to any one of examples 1 to 9, wherein the manipulation system (e.g., its capacitive manipulation member and/or each electrode thereof) comprises one or more than one pair of (e.g., beam-shaped) components (e.g., beams) between which the emission axis (e.g., emission direction) passes through, which have a greater distance from each other than two (e.g., bar-shaped) components (e.g., bars) of the anode (e.g., along a direction (x, y) running transverse to the emission axis (e.g., emission direction)).

Example 11 (e.g., a coating system) is configured according to one of examples 1 to 10, wherein the manipulation system (e.g., its capacitive manipulation member and/or each electrode thereof) comprises a or more than one pair of (e.g., beam-shaped) components (e.g., beams) between which the emission axis (e.g., emission direction) passes through, which have a distance from each other along a direction (x, y) transverse to the emission axis (e.g., emission direction) which is greater than an extension of the substrate holder along the direction.

Example 12 (e.g., a coating system) is configured according to any one of examples 1 to 11, wherein the manipulation system (e.g., its capacitive manipulation member and/or each electrode thereof) comprises a coating (e.g., each electrode thereof) comprising or consisting of, for example, titanium or a nitride.

Example 13 (e.g., a coating system) is configured according to any one of examples 1 to 12, wherein the capacitive manipulation member is arranged closer to the substrate holder than the inductive manipulation member; and/or wherein the inductive manipulation member is arranged closer to the target (or at least the target holder) than the capacitive manipulation member.

Example 14 (e.g., a coating system) is configured according to any one of examples 1 to 13, further comprising a propagation space extending along the emission axis from the target (or at least the target holder) through the anode (e.g., between two bars thereof) and/or the manipulation system to the substrate holder, wherein the propagation space is free of, for example, a solid material.

Example 15 (e.g., a coating system) is configured according to one of examples 1 to 14, wherein the anode is arranged closer to the target (or at least the target holder) than the manipulation system.

Example 16 (e.g., a coating system) is configured according to one of the examples 1 to 15, wherein the manipulation system is configured to generate a magnetic field and an electric field which are superimposed on each other.

Example 17 (e.g., a coating system) is configured according to one of examples 1 to 16, the manipulation system further comprising a magnetizable (e.g., ferromagnetic and/or soft magnetic) device (also referred to as a shim device), e.g., one or more than one magnetizable (e.g., ferromagnetic and/or soft magnetic) device (also referred to as a shim device), e.g., ferromagnetic and/or soft magnetic) segment, which extends along the emission axis (e.g., emission direction) and/or is arranged between the anode and the substrate holder, preferably at a distance from the emission axis. The shimming device improves the propagation of the magnetic field.

Example 18 (e.g., a coating system) is configured according to example 17, wherein the shim device (e.g., the one or more than one magnetizable segment) comprises two magnetizable segments between which the emission axis is arranged; and/or extends into the inductive manipulation member (e.g., its winding).

Example 19 (e.g., a coating system) is configured according to examples 1 to 18, wherein the shim device has several segments between which the emission axis is arranged and/or which are wall-shaped (then also referred to as wall) and/or plate-shaped.

Example 20 (e.g., a coating system) is configured according to examples 1 to 19, further comprising a laser (also referred to as laser source) arranged to direct a laser beam onto the target (or at least the target holder) to excite the arc discharge, e.g., a pulsed laser beam (also referred to as laser pulse).

Example 21 (e.g., a coating system) is configured according to any one of examples 1 to 20, the manipulation system comprising: a first electrical terminal for receiving electrical and/or pulsed power by which the electric field is generated; and/or one or more than one second electrical terminal for receiving electrical and/or pulsed power by which the magnetic field is generated.

Example 22 (e.g., a coating system) is configured according to any of examples 1 to 21, further comprising one or more than one electrical generator (e.g., pulse generator and/or for electrically supplying the manipulation system), each generator preferably providing a pulse power source and/or comprising: an electrical power source for providing electrical power, one or more than one switching circuit (e.g., multiple circuits), each circuit comprising: an output node (e.g., Out_1 or Out_2) for delivering the electrical power to a component of the coating system connected to the generator; a switch (e.g., T1 or T4) which couples the electrical power source on the output side to the output node; preferably a free-wheeling diode (flyback diode) which is in series with the switch and couples the electrical power source on the input side to the output node. The freewheeling diode illustratively reduces the outgoing branch of the power pulse. The component of the coating system can, for example, be a component of the manipulation system (e.g., manipulation member, coil and/or manipulation electrode) and/or an electrode (e.g., the anode or the manipulation electrode) of the coating system.

Example 23 (e.g., a coating system) is configured according to examples 1 to 22, further comprising a control device which is arranged to influence a coating process carried out by the arc discharge by changing an electrical voltage by which electrical power is supplied to the arc discharge and/or the manipulation system, based on a state (e.g., target state and/or actual state) of the coating process.

Example 24 (e.g., an electrical generator, e.g., pulse generator and/or for powering the coating system) is configured according to any of examples 1 to 23 and/or comprises: an electrical power source for providing electrical power, one or more than one circuit, each circuit comprising: an output node (e.g., Out_1 or Out_2) for outputting the electrical power to an electrode (e.g., anode or cathode) connected to the generator; a switch (e.g., T1 or T4) which couples the electrical power source on the output side to the output node; preferably a free-wheeling diode which is in series with the switch and couples the electrical power source on the input side to the output node; wherein the generator provides, for example, a pulse current source.

Example 25 (e.g., a generator) is configured according to example 23 or 24, wherein each circuit is provided by or comprises a bridge circuit (e.g., H-bridge circuit) comprising the free-wheeling diode and the switch; and/or wherein each circuit comprises two switches coupled in series with each other by the output node.

Example 26 (e.g., a generator) is configured according to any one of examples 23 to 25, wherein the one or more than one circuit comprises two circuits which are, for example, arranged in the same way as each other.

Example 27 (e.g., a generator) is configured according to one of examples 23 to 26, wherein the power source comprises a capacitive energy storage (e.g., comprising one or more than one capacitor) and/or is arranged as a pulse power source (or is at least operated as such).

Example 28 (e.g., a generator) is configured according to any one of examples 23 to 27, the circuit further comprising an electromagnetic coil which is coupled to the switch and/or the freewheeling diode by the output node and/or which couples an electrical connection of the generator to the output node.

Example 29 (e.g., a generator) is configured according to one of examples 23 to 28, wherein the switch is connected between the electrical power source and the output node (e.g., in series thereto).

Example 30 (e.g., a generator) is configured according to one of the examples 23 to 29, wherein the freewheeling diode is connected between the electrical power source and the output node (e.g., in series thereto).

Example 31 (e.g., a generator) is configured according to one of the examples 23 to 30, wherein the output node is connected between the freewheeling diode and the switch (e.g., in series thereto).

Example 32 (e.g., a generator) is configured according to one of the examples 23 to 31, wherein the output node is connected along a current path starting from the power source behind the switch and the freewheeling diode is connected along the current path behind the output node, wherein the current path terminates, for example, in the power source.

Example 33 (e.g., a generator) is configured according to one of examples 23 to 32, further comprising an electrical connection which is coupled to the freewheeling diode and the switch by the output node.

Example 34 (e.g., a generator) is configured according to any one of examples 23 to 33, further comprising: a first electrical line comprising the output node and coupling the freewheeling diode to the switch; and a second line branching from the first electrical line at the output node.

Example 35 (e.g., an electrical supply device) is configured according to any one of examples 23 to 34, wherein the one or more than one generator comprises two generators (of which each generator is configured according to any one of examples 22 to 34, for example); the example optionally further comprising: a third terminal for connecting a cathode (e.g., the target or the target holder) by which the two generators are coupled together (e.g., on the output side) (e.g., two terminals thereof).

Example 36 (e.g., a power supply device) is configured according to one of examples 22 to 35 and/or comprises: a first circuit comprising a first electrical power source, a first terminal for connecting a first anode and a first H-bridge circuit connected therebetween; and/or a first circuit comprising a second electrical power source, a second terminal for connecting a second anode (e.g., the control anode) and a second H-bridge circuit connected therebetween; further preferably comprising a third terminal for connecting a cathode (e.g., the target or the target holder), by which the first H-bridge circuit (e.g., on the output side) and the second H-bridge circuit (e.g., on the output side) are electrically coupled to each other.

Example 37 is a method comprising: supplying electrical power generated by an article according to any one of examples 22 to 36 to a coating process; varying an electrical voltage of the power source by which the electrical power is provided based on a state (e.g., target state and/or actual state) of the coating process.

Example 38 (e.g., a method) is configured according to example 37, further comprising a first driving of the power source for changing the electrical voltage of the power source; and/or a second driving of the switch for generating an electrical pulse by which the electrical power is supplied to the coating process.

Example 39 (e.g., a computer program arranged to perform the method) is configured according to example 38.

Example 40 (e.g., a computer-readable medium storing instructions, which are configured, when being executed by a processor, to cause the processor to perform the method) is configured according to example 38.

Example 41 (e.g., a control device comprising one or more than one processor arranged to perform the method) is configured according to example 38.

Example 42 (e.g., a vacuum arrangement) is configured according to one of examples 1 to 41 and/or comprising the control device according to example 41, further comprising a vacuum chamber in which the target (or at least the target holder) and/or the substrate holder are arranged.

Example 43 is using one of the examples 1 to 42 (e.g., the one or more than one electric generator and/or power supply) for electrically supplying an arc discharge by which a coating process is performed in vacuum and/or comprising a plurality of circuits; and/or for influencing a spatial propagation of a plasma formed by the arc discharge.

Example 44 is configured according to any one of examples 1 to 43, wherein the arc discharge is mediated (e.g., conveyed) between an anode and a cathode, e.g., comprising the target (or at least the target holder), of which the anode is electrically supplied (e.g., with a power pulse) by a first circuit (e.g., of the plurality of circuits) and/or of which the cathode is electrically supplied (e.g., with a power pulse) by a second circuit (e.g., of the plurality of circuits).

Example 45 is configured according to any one of examples 1 to 44, wherein the manipulation system has a distance along the emission axis from the target holder (e.g., its axis of rotation) and/or the target; wherein preferably the capacitive manipulation member (e.g., the electrode) has a distance along the emission axis from the target holder (e.g., its axis of rotation) and/or the target; and/or wherein preferably the inductive manipulation member (e.g., the electromagnet) has a distance along the emission axis from the target holder (e.g., its axis of rotation) and/or the target.

Example 46 is configured according to any one of examples 1 to 45, wherein the inductive manipulation member is provided by an electromagnet comprising, for example, one or more than one electromagnetic coil.

Example 47 is configured according to any one of examples 1 to 46, wherein the through-opening (e.g., passage opening) through which the manipulation system is penetrated along the emission axis has a first extension along a first direction (e.g., gravitational direction) which is greater than an extension of the substrate holder (e.g., the substrate) of the target holder (e.g., and/or wherein the through-opening through which the manipulation system is penetrated along the emission axis has a second extension along a second direction which is greater than an extension of the substrate holder (e.g., the substrate) of the target holder (e.g., targets) parallel thereto; wherein, for example, the first direction and the second direction are transverse to the emission axis and/or are transverse to each other.

Example 48 is configured according to one of examples 1 to 47, wherein the through-opening, through which the manipulation system (e.g., its capacitive manipulation member and/or its electrode/electrodes) is penetrated along the emission axis, has a first extension along a first direction (e.g., gravitational direction), which is greater than an extension of the substrate holder (e.g., the substrate) and/or the target holder (e.g., targets) parallel thereto; and/or wherein the through-opening has a second extension along a second direction (e.g., gravitational direction), which is greater than an extension of the substrate holder (e.g., the substrate) and/or the target holder (e.g., targets) parallel thereto. target); and/or wherein the through-opening penetrating the capacitive manipulation member (e.g., its electrode) along the emission axis has a second extension along a second direction which is larger than an extension of the substrate holder (e.g., the substrate) parallel thereto of the target holder (e.g., target); wherein, for example, the first direction and the second direction are transverse to the emission axis and/or are transverse to each other.

Example 49 is using one of examples 1 to 48, wherein the through-opening through which the manipulation system (e.g., its inductive manipulation member and/or its coil/coils) is penetrated along the emission axis has a first extension along a first direction (e.g., gravitational direction) which is greater than an extension of the substrate holder (e.g., the substrate) of the target holder (e.g., the target) parallel thereto; and/or wherein the through-opening has a second extension along a second direction (e.g., gravitational direction) which is greater than an extension of the substrate holder (e.g., the substrate) of the target holder (e.g., the target) parallel thereto. targets); and/or wherein the through-opening through which the inductive manipulation member (e.g., its coil/coils) is penetrated along the emission axis has a second extension along a second direction which is greater than an extension of the substrate holder (e.g., the substrate) of the target holder (e.g., targets) parallel thereto; wherein, for example, the first direction and the second direction are transverse to the emission axis and/or are transverse to each other.

Example 50 is using an electrical generator for powering a coating process by an arc discharge, the generator comprising: an electrical power source for providing electrical power; one or more than one circuit, each circuit comprising: an output node for outputting the electrical power to an electrode connected to the generator; a switch coupling the electrical power source to the output node on the output side; preferably a freewheeling diode in series with the switch and coupling the electrical power source to the output node on the input side.

Example 51 (e.g., the use) is configured according to any one of examples 1 to 50, wherein the one or more than one generator comprises two generators, the coating system further comprising a third terminal for connecting the target holder by which the two generators are coupled to each other.

Example 52 (e.g., using) is configured according to any one of examples 1 to 51, wherein the cathode comprises or consists of the target or at least the target holder.

Example 53 (e.g., using) is configured according to any one of examples 1 to 52, wherein the target holder is arranged to hold a target and/or is arranged to provide an axis of rotation to the target.

Example 54 is configured according to any one of examples 1 to 53, wherein electrical power (also referred to as power pulses) is supplied to the capacitive manipulation member pulser.

Example 55 is using one of examples 1 to 54, wherein electrical power (also referred to as power pulses) is supplied to the capacitive manipulation member pulser.

Example 56 is using one of examples 1 to 55, wherein the manipulation system (or at least the inductive manipulation member) is arranged between the anode and the target holder.

Example 57 is using one of examples 1 to 56, wherein the capacitive manipulation member is arranged between the anode and the target holder; or wherein the capacitive manipulation member is arranged along the emission axis behind the target holder.

### BRIEF DESCRIPTION OF THE DRAWINGS

FIG. 1A shows a coating system according to various embodiments in a schematic side view or cross-sectional view;

FIG. 1B shows various aspects of arc discharge according to different embodiments in a schematic process diagram;

FIG. 2A shows a coating system according to various embodiments in a schematic side view or cross-sectional view;

FIG. 2B shows a coating system according to various embodiments in a schematic wiring diagram;

FIG. 3A shows a generator according to various embodiments in a schematic wiring diagram;

FIG. 3B shows a generator according to various embodiments in a schematic wiring diagram; and,

FIG. 4 shows a coating system according to various embodiments in a schematic perspective view.

### DETAILED DESCRIPTION OF THE INVENTION

In the following detailed description, reference is made to the accompanying drawings which form part thereof and in which specific embodiments in which the invention may be practiced are shown for illustrative purposes. In this regard, directional terminology such as “top”, “bottom”, “front”, “rear”, “front”, “rear”, etc. is used with reference to the orientation of the figure(s) described. Since components of embodiments may be positioned in a number of different orientations, the directional terminology is for illustrative purposes and is not limiting in any way. It is understood that other embodiments may be used and structural or logical changes may be made without departing from the scope of protection of the present invention. It is to be understood that the features of the various exemplary embodiments described herein may be combined with each other, unless specifically indicated otherwise. The following detailed description is therefore not to be construed in a limiting sense, and the scope of protection of the present invention is defined by the appended claims.

In the context of this description, the terms “connected”, “connected” and “coupled” are used to describe both a direct and an indirect connection (e.g., ohmic and/or electrically conductive, e.g., an electrically conductive connection), a direct or indirect connection and a direct or indirect coupling. In the figures, identical or similar elements are provided with identical reference signs where this is appropriate. According to various embodiments, the term “coupled” or “coupling” may be understood in the sense of a (e.g., mechanical, hydrostatic, thermal and/or electrical), e.g., direct or indirect, connection and/or interaction.

Several elements may, for example, be coupled together along an interaction chain along which the interaction may be exchanged, e.g., a fluid (then also referred to as fluid-conducting coupled). For example, two coupled elements may exchange an interaction with each other, e.g., a mechanical, hydrostatic, thermal and/or electrical interaction. A coupling of several vacuum components (e.g., valves, pumps, chambers, etc.) with each other may have that they are coupled with each other in a fluid-conducting manner. According to various embodiments, “coupled” may be understood in the sense of a mechanical (e.g., physical) coupling, e.g., by direct physical contact. A coupling may be configured to transmit a mechanical interaction (e.g., force, torque, etc.).

The actual state of an entity (e.g., a device, a system or a procedure or process) may be understood as the actual or sensorily detectable state of the entity. The target state of the entity may be understood as the desired state, i.e., a specification. Control may be understood as an intended influence on the current state (also referred to as the actual state) of the entity. The current state may be changed according to the specification (also referred to as the target state), e.g., by changing one or more than one operating parameter (then also referred to as the manipulated variable) of the entity, e.g., by a manipulation member (e.g., actuator). Regulation may be understood as control, whereby a change of state is also counteracted by disturbances. For this purpose, the actual state is compared with the target state and the entity is influenced, e.g., by a manipulation member, in such a way that the deviation of the actual state from the target state is minimized. In contrast to pure forward sequential control, closed-loop control thus implements a continuous influence of the output variable on the input variable, which is brought about by the so-called control loop (also referred to as feedback). In other words, this may be understood to mean that a closed-loop control may be used as an alternative or in addition to the open-loop control (or manipulation) or that a closed-loop control may be used as an alternative or in addition to the open-loop control. The state of a controllable device (e.g., a structuring device) or a controllable process (e.g., structuring) may be specified as a point (also referred to as operating point or operating point) in a space (also referred to as state space) which is spanned by the variable parameters of the device or process (also referred to as operating parameters). The state of the device or process is therefore a function of the respective value of one or more than one operating parameter, which thus represents the state of the device or process. The actual state may be determined based on a measurement (e.g., by a measuring element) of one or more than one operating parameter (then also referred to as a controlled variable).

The term “control device” may be understood as any type of logic-implementing entity that can, for example, have a circuit and/or a processor that may execute software stored in a storage medium, in a firmware or in a combination thereof, and may issue instructions based thereon. For example, the control device may be configured by code segments (e.g., software) to control the operation of a system (e.g., its operating point), e.g., a machine or a plant, e.g., at least its kinematic chain.

The term “processor” as used herein may be understood as any type of entity that allows the processing of data or signals. For example, the data or signals may be handled according to at least one (i.e., one or more than one) specific function performed by the processor. A processor may comprise or be formed from an analog circuit, a digital circuit, a mixed signal circuit, a logic circuit, a microprocessor, a central processing unit (CPU), a graphics processing unit (GPU), a digital signal processor (DSP), a programmable gate array (FPGA), an integrated circuit, or any combination thereof. Any other type of implementation of the respective functions described in more detail below may also be understood as a processor or logic circuit. It will be understood that one or more of the method steps described in detail herein may be performed (e.g., realized) by a processor, through one or more specific functions performed by the processor. The processor may therefore be arranged to perform one of the methods or information processing components thereof described herein.

The term “system” may be understood as a set of interacting entities (e.g., members). For example, the set of interacting entities may comprise or be formed from at least one mechanical component, at least one electromechanical transducer (or other types of actuators), at least one electrical component, at least one instruction (e.g., encoded in a storage medium), and/or at least one control device.

The term “manipulation member” (e.g., including an actuator) may be understood as a transducer that is configured to manipulate (e.g., influence) a state, a process (e.g., a coating process) or a device in response to a control of the manipulation member. The manipulation member may convert an actuation signal supplied to it (by which the actuation takes place) into mechanical movements or changes in physical variables such as pressure or temperature. A manipulation member may be configured to influence the actual state (also known as the operating point) of the process (e.g., its manipulated variable), which is supplied by the manipulation member. The influence may be direct or indirect. For example, the manipulated variable and the controlled variable (e.g., sensed variable) may differ from each other. The controlled variable (e.g., pressure) may then be a function of one or more than one manipulated variable (e.g., voltage).

According to various embodiments, a bearing device may be configured for bearing (e.g., guided positioning and/or holding) one or more than one component. For example, the bearing device may have one or more than one bearing, for example per component, for bearing (e.g., guided positioning and/or holding) the component. Each bearing of the loading device may be arranged to provide the component with one or more than one degree of freedom (e.g., translational degree of freedom or rotational degree of freedom) according to which the component may be moved. Examples of a bearing include: Radial bearing, Axial bearing, Radiax bearing, Linear bearing (also known as linear guide). For example, the component may be provided with exactly one degree of translational freedom per linear bearing.

According to various embodiments, the vacuum chamber may be or may be provided by a chamber housing, in which one or more chambers may be or may be provided. The chamber housing can, for example, be coupled to a pump arrangement, e.g., a vacuum pump arrangement (e.g., gas-conducting), to provide a negative pressure or a vacuum (vacuum chamber housing) and may be configured in such a stable manner that it may withstand the effect of the air pressure in the pumped-down state. The pump arrangement (comprising at least one vacuum pump, e.g., a high-vacuum pump, e.g., a turbomolecular pump) may enable a portion of the gas to be pumped from the interior of the processing chamber, e.g., from the processing chamber. Accordingly, one or more vacuum chambers may be provided in a chamber housing. In other words, the chamber housing may be configured as a vacuum chamber housing or a coating chamber may be configured as a vacuum chamber.

As used herein, the term “vacuum pressure” means a negative pressure in the range of vacuum (i.e., a pressure of less than 0.3 bar), e.g., a pressure in a range of about 10 mbar to about 1 mbar (in other words rough vacuum) may be provided or less, e.g., a pressure in a range from about 1 mbar to about 10-³ mbar (in other words fine vacuum) or less, e.g., a pressure in a range from about 10-³ mbar to about 10-⁷ mbar (in other words high vacuum) or less, e.g., a pressure of less than high vacuum, e.g., less than about 10-⁷ mbar.

A drive device may be understood herein as a converter which is adapted to convert electrical energy into mechanical energy. A drive device can, for example, have an electric motor (e.g., with electric coils). A drive device can, for example, have a compressor and a reciprocating piston coupled to it. A drive device may, for example, have one or more than one piezo element. For example, the drive device may be configured to output the mechanical energy by a torque or a rotary movement.

Arc vaporization is understood to be the conversion of a solid vaporization material into a gaseous aggregate state by arc discharge. The target material, when converted to the gaseous aggregate state, may be used as a coating material, e.g., as the layer forming material.

Arc evaporation, i.e., evaporation by an arc discharge, belongs to the class of thermal evaporation processes, which have in common that a material to be evaporated (also referred to herein in simplified terms as coating material) is heated in such a way that it changes to its gaseous state (also referred to as material vapor) (e.g., by absorbing latent heat). A melt of the material may (but does not necessarily have to) be present as an intermediate step. For example, it may evaporate from the melt or sublimate directly. An arc discharge is a form of gas discharge in which the plasma formed in the process is drawn together to form a tube (or thin thread, the so-called arc). Within the plasma tube formed in this way, high gas temperatures (e.g., in a range from approximately 5000 Kelvin to approximately 50000 Kelvin), currents (e.g., in a range of approximately 2000 amperes or more) and gas pressures occur, by which the coating material is converted into the gaseous phase (also known as vaporization). The arc discharge and thus the plasma formation may be of short duration so that it is pulsed. Arc evaporation must be distinguished from the process of sputtering, in which the plasma is generated by a (e.g., continuous or pulsed) glow discharge.

In a variant of arc evaporation, a laser is used to control the ignition of the arc discharge, which locally stimulates the formation of a plasma (also referred to as laser-induced or laser-assisted arc discharge or laser arc). Here, the laser generates a very short-pulsed plasma inside the plasma chamber between the anode and the cathode (for discharge ignition of an initial plasma). This initial plasma of a few 10 ns (nanoseconds) to 100 ns duration is then amplified in pulse length and power by an arc discharge using an electrical (pulse) supply device (e.g., a pulse current source). The plasma formed in this way lowers the impedance between the cathode and anode, so that a voltage applied between them leads to a discharge current through the plasma. In other words, a pulsed arc discharge may be excited using of the laser. The laser is guided over the cathode by a mirror system so that the location of the arc discharge may be changed in a targeted manner. The laser influences the location of the discharge ignition on the cathode and thus ensures uniform contact-free removal of the target material.

An excitation source (e.g., laser source) is a device that is configured to generate an excitation pulse, for example a radiation pulse, a power pulse (e.g., conveyed as a current pulse or a voltage pulse) or similar. The excitation source is generally configured to excite (e.g., trigger) a plasma discharge (e.g., a plasma formation and/or an electrical charge transfer by the plasma) by the excitation pulse. For example, an electrical voltage pulse may be used as an excitation pulse to trigger the plasma discharge. A laser source is a device that is configured to generate a laser beam. A laser beam is understood to be a directed (e.g., collinear and/or collimated) propagation of electromagnetic waves, which is, for example, stimulated and/or coherent. The laser source can, for example, have an electromagnetic resonator by which the stimulated emission of the laser beam takes place. In contrast to a continuous wave laser, a pulsed laser source generates pulsed laser radiation (also known as a laser pulse). The laser pulse may be generated by pulsed excitation or, for example, by a Q-switch in the laser itself. Examples of the laser source include Gas lasers (e.g., carbon dioxide lasers) and solid-state lasers (e.g., semiconductor lasers).

In a modification of arc evaporation (also known as ARC evaporation), a laser is used to control the ignition of the arc discharge, which locally stimulates the formation of a plasma (also known as laser-induced or laser-assisted arc discharge). Here, the laser generates a very short pulsed plasma inside the plasma chamber between the anode and the cathode (for discharge ignition of an initial plasma). This initial plasma of a few 10 ns (nanoseconds) to 100 ns duration is then amplified in pulse length and power by an arc discharge using an electrical supply device (e.g., pulse generator and/or pulse current source). The plasma thus formed lowers the impedance between cathode and anode, so that a voltage U_arc (also known as arc voltage) applied between cathode and anode leads to a discharge current through the plasma. In other words, the laser may be used to excite a pulsed arc discharge.

A “pulse” in relation to a physical quantity (e.g., power, then also referred to as a power pulse) may be understood as a change in the quantity over time such that the value of the quantity increases (e.g., starting from an initial value, e.g., zero), exceeds a maximum (also referred to as a peak value) and then decreases again (e.g., to the initial value).

A plasma may be formed by a so-called working gas (also referred to as a plasma-forming gas). According to various embodiments, the working gas may comprise a gaseous material which is inert, in other words, which participates in few or no chemical reactions. For example, a working gas may be or be defined by the target material used and be or be adapted to it. For example, a working gas may be a gas or a gas mixture that does not react with the target material to form a solid. The working gas can, for example, contain a noble gas (e.g., helium, neon, argon, krypton, xenon, radon) or several noble gases. The plasma may be formed from the working gas, which essentially atomizes the target material, for example. If a reactive gas is used, this may have a higher chemical reactivity than the working gas, e.g., with regard to the target material. In other words, the atomized target material together with the reactive gas (if present) may react faster (i.e., form more reaction product per time) than together with the working gas (e.g., if it reacts chemically with the working gas at all). The reactive gas and the working gas may be supplied together or separately as a process gas (e.g., as a gas mixture), for example by the gas supply device.

As used herein, an electrode is understood to be an electrically conductive and/or metallic object (e.g., body or combination of several bodies) to which an electrical potential (also referred to as electrode potential) may be applied during operation and/or to which the electrical potential may be changed. For example, the electrode may have one or more than one plate-shaped component (also referred to as an electrode plate), one or more than one wire-shaped component (also referred to as an electrode wire) and/or one or more than one bar-shaped component (also referred to as an electrode bar). The electrode may further be electrically coupled to a circuit which is, for example, arranged to provide the electrode potential. Depending on the implementation, an electrode may be configured as an anode or a cathode and operated accordingly. The electrode may be used, for example, to supply electricity to the coating process.

As used herein, the term “coating material” generally refers to a material by which a coating process may be carried out in which one or more than one layer is formed (also referred to as coating). The coating material may, for example, have the chemical composition of the layer (then also referred to as layer-forming material) or react chemically to the layer-forming material. Alternatively or additionally, the coating material may be or be arranged in a crucible (then also referred to as evaporation material).

Reference is made herein, inter alia, to an axis of rotation, in particular for a rotatably mounted component (e.g., target or substrate) and/or a storage device (e.g., the target holder or substrate holder) configured for storing the same. In this respect, it may be understood that what is described for the axis of rotation may apply by analogy to an axis of longitudinal extension, for example if there is no rotatable mounting.

For ease of understanding, reference is made herein to the extension of the target and substrate. According to various embodiments, the substrate holder may have a receiving area (e.g., a cavity) for receiving the substrate. In this case, what is described for the expansion of the substrate may apply by analogy to the expansion of the receiving area, for example if no substrate is present. Alternatively or additionally, the target holder may have a receiving area (e.g., a cavity) for receiving the target. In this case, what is described for the expansion of the target may apply by analogy to the expansion of the receiving area, for example if no target is present.

The term “soft magnetic” may be understood as having a coercive field strength of less than about 500 kA/m, e.g., less than about 100 kA/m, e.g., less than about 10 kA/m, e.g., less than about 1 kA/m. A soft magnetic component may, for example, comprise or be formed from an alloy comprising iron, nickel and/or cobalt, steel, a powder material and/or a soft ferrite (e.g., comprising nickel tin and/or manganese tin).

The coil axis is understood herein as the axis of a coil around which the electrical line of the coil extends in order to provide the windings of the coil. The coil axis may, for example, denote the axis of symmetry of the coil. For example, the turns of a coil may follow a helix. The helix may run along a curve on the lateral surface of a cylinder. In this case, the cylinder axis coincides with the coil axis. If the windings of a real coil deviate from such an ideal helix, a helix may generally be found which on average has the smallest spatial deviation from the windings of the coil. This helix may then define the cylinder axis, as described above, which coincides with the coil axis. Optionally, the or each coil may be multi-layered, i.e., it may have multiple layers, each layer of which may have multiple turns. The windings of each layer of the coil may have a common coil axis, e.g., if they follow a helix with a common cylinder axis.

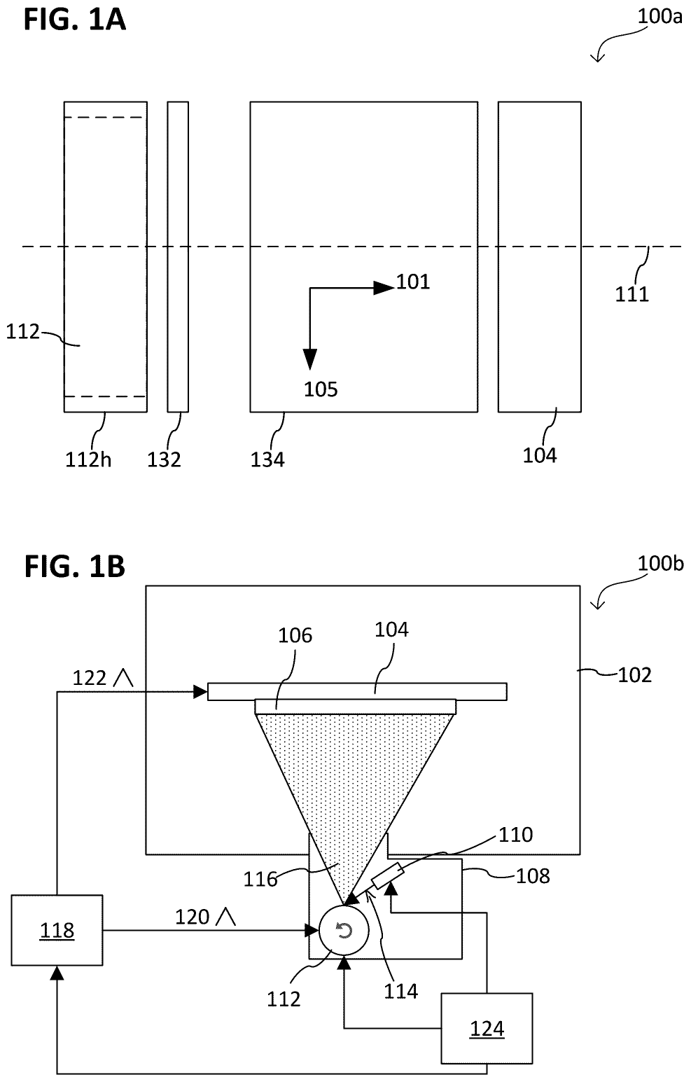

FIG. 1A illustrates a coating system according to various embodiments 100a in a schematic side view or cross-sectional view, preferably configured according to example 1. The target holder 112h may have a receiving area for receiving the target 112, which is held by the target holder 112h, and may for example be dismantled outside the operation of the coating system.

The emission axis 111 (also referred to as the propagation axis) extends along an emission direction 101, which is directed from the target holder 112h towards the substrate holder 104. Arranged in series along the emission direction 101 are: the anode 132, the manipulation system 134, and the substrate holder 104. An exemplary implementation of the emission axis 111 is oriented transverse or parallel to the gravitational direction 105 (i.e., direction of the gravitational force).

An exemplary implementation of the target 112 is rotatably supported by a bearing device as a target holder (not shown). This extends the service life of the target, in particular if it is rotated during operation, for example during arc evaporation. The axis of rotation of the target 112 can, for example, be aligned transversely to the emission axis 111.

By analogy, an exemplary implementation of the substrate holder 104 has a bearing device by which the substrate may be rotatably mounted. The axis of rotation of the substrate can, for example, be along the axis of rotation of the target 112. Alternatively, the substrate holder 104 may be arranged to transport the substrate along a transport direction past the target 112, for example by one or more than one transport roller of the substrate holder 104. In that case, the substrate may be plate-shaped or ribbon-shaped.

The anode 132 is arranged to excite the formation of an arc discharge during operation, which is mediated between the target and the anode. By the arc discharge, a part of the target 112 may be transferred into the gaseous phase and the material thus separated from the target 112 may spread (at least partially as plasma) in the direction of emission 101 towards the substrate holder (also referred to as material flow 116, see FIG. 1B).

An exemplary implementation of the manipulation system 134 has one or more than one electromagnetic coil and/or one or more than one electrostatic electrode, as will be described in more detail below. The operating parameters of the manipulation system 134 span additional dimensions for influencing the material flow 116.

FIG. 1B illustrates aspects for arc discharge according to various embodiments 100b in a schematic process diagram, preferably configured according to embodiment 100b and/or example 20, by which arc evaporation (for example for laser-induced arc evaporation) may take place. Illustratively, these aspects improve the properties of the intermediate layer and/or increase the latitude in selecting the operating point (AP) when forming the intermediate layer.

These aspects of the arc discharge may be implemented, for example, by a device, such as a vacuum arrangement and/or a control device, and/or by the method. For simplified understanding, reference is made to the implementation by the vacuum arrangement, whereby what is described for this may apply by analogy to any of the other implementations. Pulsed signals are identified by a circumflex “\hat{ }”. Furthermore, for simplified understanding, reference is made to a laser-excited arc discharge, in which an arc discharge is excited by a laser pulse. What is described here may be understood as applying by analogy to any other type of plasma discharge, which does not necessarily have to be an arc discharge and/or does not necessarily have to be excited by a laser pulse.

An exemplary implementation of the vacuum arrangement (preferably according to Example 42) comprises a vacuum chamber 102. The or each vacuum chamber 102 may optionally comprise a chamber lid which seals the interior of the vacuum chamber 102 in a vacuum-tight manner. Accordingly, the arc discharge may be exposed to a process pressure (e.g., vacuum pressure) and/or a process gas. The vacuum arrangement further comprises a coating device 108. The coating device 108 may be configured to coat the substrate 104 using a laser-induced arc discharge.

The particular gas pressure (also referred to as process pressure) used to operate the coating device 108 and/or the particular process gas (e.g., a gas or gas mixture) supplied to the coating device 108 may be highly application dependent. For example, the process pressure may be in a range from about 10⁻⁴ mbar (millibar) to about 5·10⁻⁴ mbar. For example, the process gas may comprise one or more than one of the following gases: Oxygen (e.g., molecular oxygen, i.e., O₂), Nitrogen (e.g., molecular nitrogen, i.e., N₂), Hydrogen (e.g., molecular hydrogen, i.e., H₂), one or more than one hydrocarbon compound, or a gas mixture thereof. The process gas may comprise the working gas (e.g., an inert gas) and/or a reactive gas. The optional reactive gas may, for example, comprise hydrogen.

An exemplary implementation of the coating system has a coating device 108, which has a target holder (not shown) for holding the target 112. The target 112 may generally comprise or consist of a vaporization material (e.g., the coating material) that is to be converted to a gaseous state. The target holder may, for example, provide the target 112 with an axis of rotation and may be arranged to cause the target 112 (when held in the target holder) to rotate about the axis of rotation, for example by a drive device. The coating device 108 optionally has a laser source 110.

An exemplary implementation of the coating device (preferably according to example 20) comprises the laser source 110 arranged to generate and direct one or more than one laser pulse 114 (i.e., pulsed laser beam) onto the target holder, or at least the target 112.

In an exemplary implementation of the operation of the vacuum arrangement, the target 112 is held in the target holder and is repeatedly irradiated with a laser pulse 114 by the laser source 110. This laser pulse 114 may excite (e.g., induce) an arc discharge at the target 112, during which a portion of the target is converted into material vapor. In this case, the target 112 may be operated as a cathode. Therefore, the target holder may also be referred to as a cathode end block).

A device may be referred to as a cathode end block (hereinafter also referred to simply as an end block), which is configured to hold and supply a cathode, for example with a torque for rotating the cathode, with electrical energy and optionally with a cooling fluid. To provide the torque, the end block may have a drive device (e.g., a motor) or at least be coupled to one. The end block may be attached inside a vacuum chamber, e.g., to a through-opening (e.g., passage opening) in the chamber wall (also referred to as a supply opening). The electrical energy and/or the cooling fluid (and optionally the torque) may be supplied to the end block through the supply opening. Optionally, one or more than one additional medium may be supplied to the end block, which serves to supply the cathode, e.g., data for controlling and/or for reading out a sensor.

An exemplary implementation of the target 112 is tubular (then also referred to as a tubular target). For example, the target 112 may have a tubular carrier (a so-called carrier tube) to which a (e.g., brittle and/or fragile) coating material may be attached. The diameter of the tubular target may, for example, be in a range from about 10 cm (centimeters) to about 50 cm, e.g., about 20 cm or more.

The vacuum assembly may include one or more than one electrical supply device 118 (may also be referred to as an electrical power supply). Each electrical power supply device 118 may be arranged to provide one or more than one operating voltage (e.g., a DC voltage), e.g., pulsed (also referred to as a voltage pulse). Alternatively or additionally, the electrical supply device 118 may have, for example, a pulse generator (preferably configured according to Example 22) for each power pulse to be provided.

The operating voltage must be applied between the anode and the target holder. The operating voltage to be applied may be set in such a way that an electric current may discharge between the anode and the cathode, but no spontaneous discharge ignition (uncontrolled start of discharge). For this purpose, the operating voltage may be lower than the ignition voltage (i.e., the voltage at which an arc discharge is ignited) and higher than a burning voltage (i.e., the voltage at which an arc discharge occurs). For example, an anode potential at the anode may range from approximately 10 to approximately 20 V. For example, a cathode potential at the cathode may be negative (e.g., with respect to electrical ground) and/or its magnitude may be in a range from about 240 V to about 350 V.

An exemplary implementation of the electrical supply device 118 is arranged to generate a first electrical power pulse 120. The first electrical power pulse 120 may be applied to the target 112. The first electrical power pulse 120 may be arranged to electrically supply the arc discharge (induced by the laser pulse 114) (e.g., by the target 112). For this purpose, the target holder may be electrically coupled to the electrical supply device 118.

The vacuum arrangement may comprise a control device 124. The control device 124 may be arranged to control the laser source 110. For example, the control device 124 may control the laser source 110 to generate the laser pulse 114 to initiate a laser-induced arc discharge. The control device 124 may be arranged to control the electrical supply device 118 and/or the laser source 110. For example, the control device 124 may control the electrical supply device 118 to generate the first electrical power pulse 120 according to a (first) target power pulse (e.g., a target current pulse). The first electrical power pulse 120 may be imparted by a current pulse generated (or controlled) by the electrical supply device 118.

If reference is made herein to a specification, such as a target power pulse and/or characteristics thereof (e.g., a target power pulse, a target time delay, and/or a target frequency, etc.), this may be implemented by code segments, which may be stored, for example, in a data memory associated with the control device 124. The code segments may be stored in the data memory in a suitable manner, for example as a list (e.g., table), series of values, as an algorithm, etc.

A manipulation performed by the control device 124 may be performed according to an operating sequence. This operating sequence may be stored in the data memory in a suitable manner, for example as an algorithm or otherwise by code segments.

An exemplary implementation of the drive device is configured to stimulate a rotational movement of the target 112 about an axis of rotation. For example, the target holder may have the drive device (e.g., an electric motor) for this purpose, which is configured to supply a torque to the target. The control device 124 may be arranged to control the drive device in order to control the rotational movement (e.g., a rotational frequency).

By the arc, the (e.g., solid) target may be at least partially (for example at the discharge point on the target 112) transferred into the gaseous aggregate state (simplified also referred to as gaseous state or as vapor). In simplified terms, the transfer may also be referred to as vaporization, but may generally also involve sublimation (i.e., a direct transition from the solid aggregate state of the target material to the gaseous state). The material released from the target 112 (e.g., vaporized from the target 112) by the arc discharge may form a material stream 116 away from the target 112.

During operation of the vacuum arrangement, one (or more than one) substrate 106 may be coated using the material stream 116. For this purpose, the vacuum arrangement may comprise a substrate holder 104 that is arranged to hold and/or transport the one or more than one substrate 104 (then also referred to as transport device 104). The substrate holder 104 may be arranged in the vacuum chamber 102. In various embodiments, a distance between the axis of rotation and the substrate holder may be in a range from about 410 mm to about 750 mm.

An exemplary implementation of the transport device 104 is configured to transport a tape-shaped substrate (also referred to as a tape substrate), for example from roll to roll. Here, the transport device 104 may hold a first roll from which the tape substrate is unwound and a second roll onto which the tape substrate is wound after it has been exposed to the material flow 116.

An exemplary implementation of the electrical supply device 118 is arranged to generate a second electrical power pulse 122. The second electrical power pulse 122 may be arranged to accelerate the (e.g., ionized portion of the) material stream 116 away from the target 112 or towards the substrate holder 104. For this purpose, the substrate holder 104 may be electrically coupled to the electrical supply device 118. The second electrical power pulse 122 may be used to influence a kinetic energy with which the material of the material stream 116 strikes the substrate 106.

According to various aspects, the laser pulse 114, the first electrical power pulse 120, and optionally further the second electrical power pulse 122, e.g., one or more than one characteristic (e.g., time dependency, frequency, and/or pulse duration) thereof, may be linked together (e.g., by the operating sequence), e.g., such that they overlap each other in time. To this end, the control device 124 may include, for example, a clock that implements a linkage of the laser pulse 114, the first electrical power pulse 120, and optionally further the second electrical power pulse 122 with each other.

According to various aspects, the substrate 106 may be coated by repeatedly (according to a target frequency) generating a respective arc discharge with associated material flow 116 (also referred to as discharge ignition). As used herein, discharge ignition is understood to mean the (for example repeated) excitation of the arc discharge by one or more than one pulse, for example by the laser pulse 114 and by the first electrical power pulse 120. The laser pulse 114, the first electrical power pulse 120 and optionally the second electrical power pulse 122 may be generated per discharge ignition.

The power supply device 118 described herein may also be implemented using one or more than a single device, of which, for example, a first device generates the first power pulse and a second device generates the second power pulse.

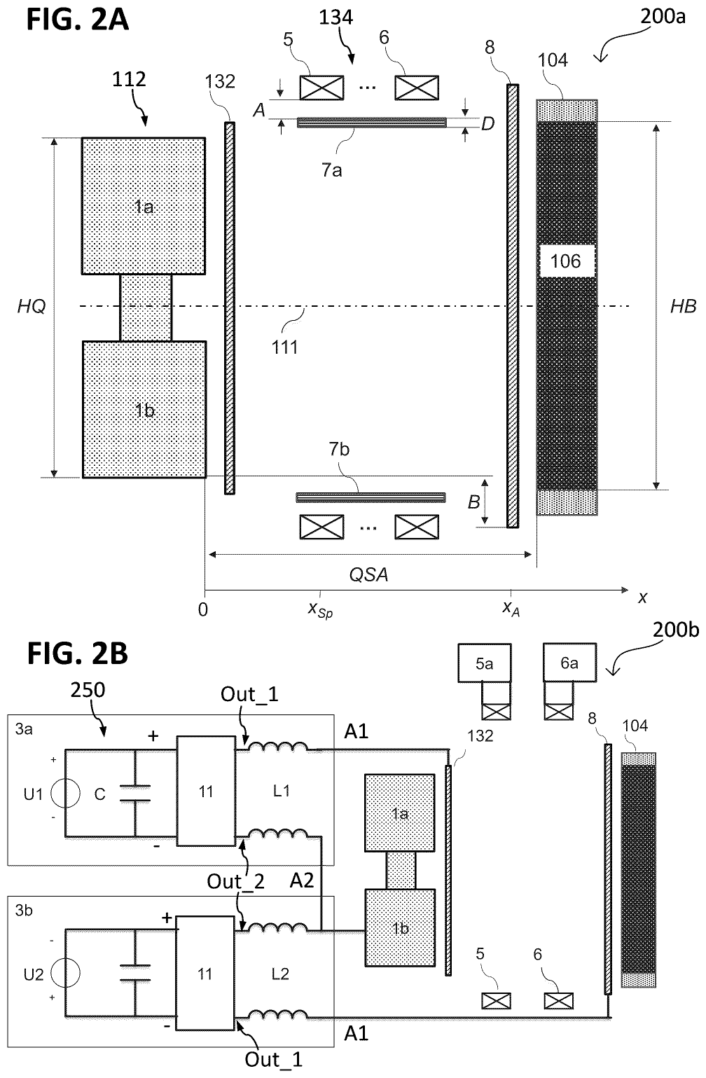

FIG. 2A illustrates the coating system according to various embodiments 200a in a schematic side view or cross-sectional view, preferably configured according to embodiments 100a to 100b and/or according to example 2.

An exemplary implementation of the capacitive manipulation member of the manipulation system 134 has an electrode 8 (also referred to as a manipulation electrode) for generating the electric field, which is configured as an anode (then also referred to as a positioning anode).

An exemplary implementation of the inductive manipulation member (preferably according to Example 3) of the manipulation system 134 has a plurality of electromagnetic coils 5, 6 arranged in series along the emission axis 111, e.g., two or more electromagnetic coils 5, 6, for generating the magnetic field. Each of the coils has several windings around the emission axis 111, so that the coil is penetrated along the emission axis 111 by the propagation space (preferably according to example 14).

Optionally, the inductive manipulation member (preferably according to example 3) has a plurality of magnetizable (e.g., ferromagnetic and/or soft magnetic) walls 7a, 7b (e.g., plates) as shim device, between which the emission axis 111 is arranged and which extend into one or more than one of the coils 5, 6.

An exemplary implementation of the target 112 has several segments 1a, 1b, between which the target 112 is tapered. This improves the plasma propagation.

Exemplary implementations of the geometry (also referred to as) geometry examples of the coating system that improve the coating process are explained below:

According to geometry example 1, substrate 106 is disposed at a distance QSA (also referred to as source-substrate distance) from target 112; inductive manipulation member is disposed at a distance xSP from target 112; and capacitive manipulation member is disposed at a distance xA from target 112. Further, one or more than one of the following relations may be satisfied:

$$\begin{matrix}QSA > x A > xSP ; and / or \\ QSA - xA > xSP .\end{matrix}$$

According to Geometry Example 2, an extension D of each of the walls (also referred to as wall thickness D) in the direction away from the emission axis 111 is greater than 1 mm, e.g., as 5 mm, e.g., as 10 mm, e.g., as 20 mm (millimeters). Alternatively or additionally, a distance A of each of the walls from the turns of each coil is greater than the wall thickness D.

According to Geometry Example 3, a reference direction (e.g., gravitational direction 105) is transverse to the emission axis 111 and/or along the axis of rotation of the target 112 (and/or the substrate holder 104). Along the reference direction, the target has an extension HQ (also referred to as target height); the capacitive manipulation member 8 (or passage) has an extension T=HQ+B; and the substrate has an extension HB. Furthermore, one or more than one of the following relations may be fulfilled:
B>0 (also referred to as protrusion B);

$$\begin{matrix}T > HB and / or T > HQ ; \\ HB > HQ .\end{matrix}$$

The protrusion illustratively improves the coating process.

According to geometry example 4, one or more of the following relations is fulfilled:

$$\begin{matrix}T > QSA and / or HB > QSA ; \\ B > D and / or B > A ; \\ HQ > QSA\end{matrix}$$

According to geometry example 5, a transverse direction is transverse to the emission axis 111 and transverse to the reference direction (e.g., gravitational direction 105). Along the transverse direction, the target has an extent B_T (also referred to as target width); the capacitive manipulation member 8 (or passage) has an extent B_A; and the substrate has an extent B_S. Furthermore, one or more than one of the following relations may be fulfilled:

$$\begin{matrix}B\_A > B\_S and / or B\_A > B\_T ; \\ B\_T > B\_S .\end{matrix}$$

This illustratively improves the coating process.

FIG. 2B illustrates the coating system according to various embodiments 200b in a schematic interconnection diagram, preferably configured according to embodiments 100a to 200a and/or according to example 22.

An exemplary implementation of the supply device 118 has a plurality of generators 3a, 3b, each generator of which is configured as a pulse generator and has two output-side connections A1, A2. Various exemplary implementations of a generator (also referred to as generator examples) of the supply device 118 are described below, wherein the described may preferably apply to each of the generators 3a, 3b. For this purpose, it may be understood that the generator or at least the supply device 118 may also be provided individually.

According to generator example 1, a first terminal A1 (also referred to as the output-side anode terminal) of the two terminals of the generator is electrically coupled to an anode (e.g., the anode 132 or the auxiliary anode) in order to supply a power pulse to the anode.

According to generator example 2, a second connection A2 (also referred to as the cathode connection on the output side) of the two connections of the generator is electrically coupled to the target holder in order to provide the operating voltage between the anode connection A1 and the target holder. If there are two generators, their output-side cathode connections may be ohmically coupled to each other, for example.

According to generator example 3, the generator has one circuit per connection of the two connections A1, A2, the output node of which is coupled to the connection by an electromagnetic coil L1, L2. Each circuit can, for example, be provided by a bridge circuit 11, e.g., an H-bridge circuit 11 (also referred to as an H-bridge), as will be explained in more detail later.

According to generator example 4, the power source 250 of the generator has a power source U1, U1 (e.g., a power supply unit) which is configured to provide a DC voltage, e.g., the operating voltage. The power source can, for example, have a converter (e.g., power supply unit), which is configured to convert an AC voltage (e.g., mains voltage of a public power grid) into the DC voltage.

According to generator example 5, the power source 250 of the generator has a capacitive power storage device, for example implemented by one or more than one capacitor. The capacitive power storage device may, for example, have a capacitance C.

Furthermore, the supply device 118 has, for each coil of the electromagnetic manipulation member, a direct current source 5a, 6a for supplying the coil with a direct current.

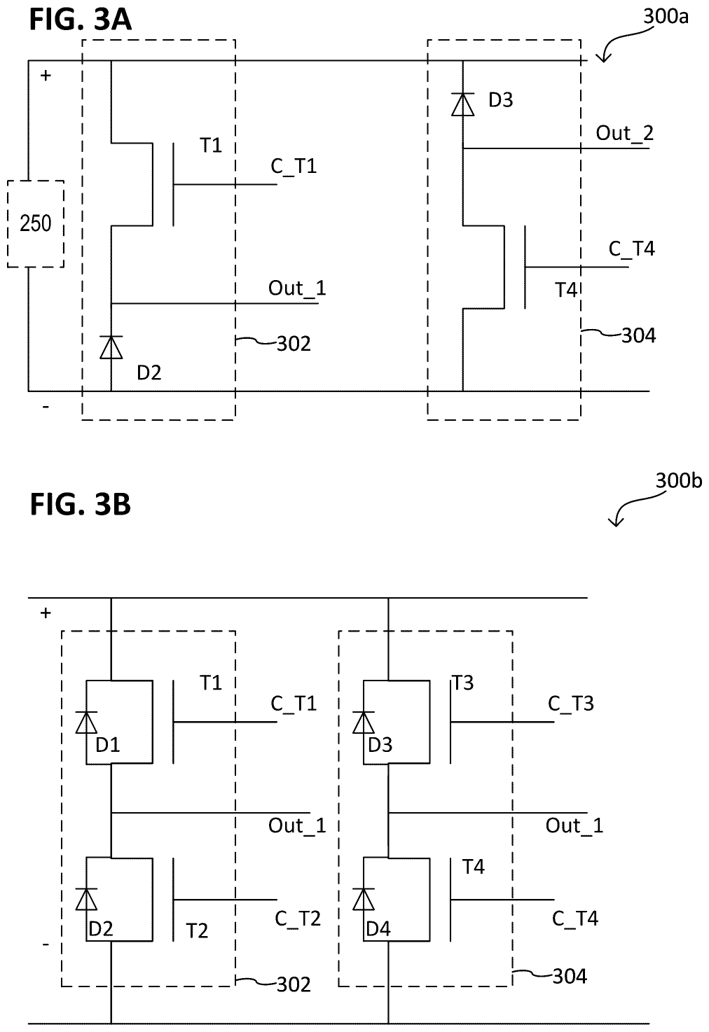

FIG. 3A illustrates a generator according to various embodiments 300a in a schematic circuit diagram, preferably configured according to embodiments 100a to 200b and/or according to example 24.

According to generator example 6, the first terminal A1 of the generator is coupled to a first circuit 302 (e.g., its output node Out_1) by a first coil and the second terminal A2 of the generator is coupled to a second circuit 304 (e.g., its output node Out_2) by a second coil.

According to generator example 7, the generator has two switching circuits 302, 304, which are connected in parallel to each other and/or of which each switching circuit is connected between the two outputs (+,−) of the power source 250. In the following, various exemplary implementations of a switching circuit (also referred to as switching circuit examples) of the generator are described, whereby the described may preferably apply to each of the switching circuits 304.

According to circuit example 1, one or more than one switch T1, T4 of the circuit is implemented by an insulated gate bipolar transistor (IGBT).

According to circuit example 2, one or more than one switch T1, T4 of the circuit is coupled to a control input C_T1, C_T4 of the circuit and is arranged to be switched by a control signal applied to the control input. The control signal can, for example, be generated by the control device.

According to circuit example 3, the freewheeling diode D2 and the switch T1 of the circuit are coupled to each other in series and/or by the output node Out_1, Out_2.

According to circuit example 4, there is one circuit 302, 304 per output of the generator, the output node Out_1, Out_2 of which is coupled to the output of the generator by an electrical coil L.

FIG. 3B illustrates a generator according to various embodiments 300b in a schematic circuit diagram, preferably configured according to embodiments 100a to 300a and/or according to example 22. The generator has an H-bridge circuit which provides the two circuits.

According to circuit example 5, the circuit has two assemblies comprising switch Ti and free-wheeling diode Di (i=,1,2,3,4), the two assemblies being coupled to each other in series and by an output node. Each of the assemblies has a switch Ti and a freewheeling diode Di, which are connected in parallel to each other.

The H-bridge circuit thus provides a closed mesh along which four modules are connected in series one behind the other and which has the two output nodes at which an output is branched off. The H-bridge circuit enables a cost-effective implementation of the generator.

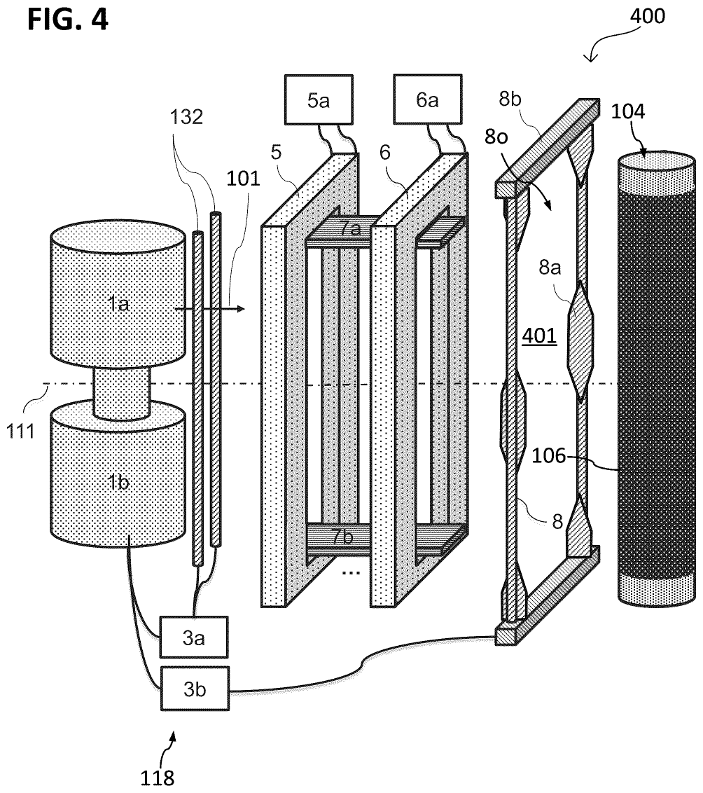

FIG. 4 illustrates the coating system according to various embodiments 400 in a schematic perspective view, preferably configured according to embodiments 100a to 300b and/or according to example 6.

An exemplary implementation of the manipulation electrode 8 (preferably according to example 7) has four electrode bars 8a, 8b, which form a frame. The electrode bars 8a, 8b run around a through-opening 80 (e.g., passage opening), through which the manipulation electrode 8 passes. Two of the electrode bars 8a, 8b are disposed on opposite sides of the through opening 80. The propagation space 401 (preferably according to example 14) may extend along the emission direction 101 from the target 1 through the through-opening 80.

An exemplary implementation of the anode 132 has two bars disposed on opposite sides of the propagation space 401.

An exemplary implementation of the supply device 118 has two generators 3a, 3b. A first generator 3a of the two generators 3a, 3b is configured as a pulse generator and is configured to supply electrical power (e.g., pulsed) to the anode 132. For this purpose, the anode connection A1 of the first generator 3a may be ohmically coupled to the anode 132. A second generator 3b of the two generators 3a, 3b is configured as a pulse generator and is configured to supply electrical power (e.g., pulsed) to the manipulation electrode 8. For this purpose, the anode connection A1 of the second generator 3b may be ohmically coupled to the manipulation electrode 8. Furthermore, the cathode connection A2 of each generator of the two generators 3a, 3b may be coupled to the target holder (or at least the target).

An exemplary implementation of the supply device 118 has one direct current source 5a, 6a per coil 5, 6 of the electromagnetic manipulation member for supplying the coil 5, 6 with a direct current.

1. A coating system for coating a substrate by an arc discharge, comprising
a target holder for holding a target;
a substrate holder arranged, along an emission axis, behind the target holder for holding a substrate to be coated by the target;
an anode for generating an arc discharge mediated between the target and the anode, the anode being disposed between the target holder and the substrate holder; and,
a manipulation system disposed along the emission axis behind the anode, which is configured to generate an electric and/or magnetic field for influencing a plasma emitted by the arc discharge from the target holder along the emission axis.

2. The coating system according to claim 1, wherein the manipulation system comprises a capacitive manipulation member for generating the electric field and/or an inductive manipulation member for generating the magnetic field, which are arranged along the emission axis behind the anode.

3. The coating system according to claim 2, wherein the inductive manipulation member comprises one or more than one electromagnetic coil for generating the magnetic field.

4. The coating system according to claim 3, wherein the one or more than one electromagnetic coil comprises two coils which are arranged in series along the emission axis.

5. The coating system according to claim 3, the manipulation system further comprising a magnetizable device, which extends into the one or more than one electromagnetic coil.

6. The coating system according to claim 3, wherein the one or more than one electromagnetic coil provides at least one electric winding around the emission direction, such that the plasma propagates through the electromagnetic coil towards the substrate holder.

7. The coating system according to claim 2, wherein the capacitive manipulation member is frame-shaped and is penetrated along the emission axis by a through-opening.

8. The coating system according to claim 2, wherein the capacitive manipulation member has a larger extension than the anode.

9. The coating system according to claim 2, wherein the capacitive manipulation member comprises one or more than one pair of bars between which the emission axis passes, which have a greater distance from each other than two supports of the anode.

10. The coating system according to claim 2, wherein the capacitive manipulation member comprises a coating comprising or consisting of titanium or a nitride.

11. The coating system according to claim 1, wherein the manipulation system is arranged to generate a magnetic field and an electric field which are superimposed on each other.

12. The coating system according to claim 1, the manipulation system further comprising two magnetizable segments, each segment extending along the emission axis and being arranged between the anode and the substrate holder, wherein the emission axis is arranged between the two segments.

13. The coating system according to claim 1, further comprising a laser adapted to direct a laser beam onto the target holder for exciting the arc discharge.

14. The coating system according to claim 1, further comprising a control device adapted to influence a coating process performed by the arc discharge by changing an electric voltage by which electric power is supplied to the manipulation system based on a state of the coating process.

15. The coating system according to claim 1, further comprising one or more than one electrical generator, of which each generator comprises:
an electrical power source for providing electrical power,
one or more than one switching circuit,
each circuit comprising:
an output node for outputting the electrical power to the manipulation system connected to the generator;
a switch which couples the electrical power source to the output node on the output side; and,
a freewheeling diode, which is in series with the switch and couples the electrical power source on the input side to the output node.

16. The coating system according to claim 12, wherein the one or more than one circuit comprises two circuits, each circuit being provided by a bridge circuit comprising the free-wheeling diode and the switch.

17. The coating system according to claim 12, wherein each switching circuit further comprises an electromagnetic coil coupled to the switch by the output node and coupling an electrical connection to the output node.

18. The coating system according to claim 12, wherein the one or more than one generator comprises two generators, the coating system further comprising a third terminal for connecting the target holder, by which the two generators are coupled to each other on the output side.

19. A coating system for coating a substrate by an arc discharge, comprising
a target holder for holding a target;
a substrate holder arranged, along an emission axis, behind the target holder for holding a substrate to be coated by the target;
an anode for generating an arc discharge mediated between the target and the anode, the anode being disposed between the target holder and the substrate holder; and,
one or more than one electromagnetic coil disposed along the emission axis behind the anode, the one or more than one electromagnetic coil being configured to generate a magnetic field for influencing a plasma emitted by the arc discharge from the target holder along the emission axis.

20. A method, comprising:
generating a plasma by an arc discharge, the plasma being emitted from a target along the emission axis to a substrate, the arc discharge being mediated between the target and an anode, the anode being disposed between the holder and the substrate, wherein the substrate is disposed, along the emission axis, behind the target; and,
manipulating the plasma by a magnetic field generated by one or more than one electromagnetic coil disposed along the emission axis behind the anode.
